(19) United States
(12) Patent Application Publication
(10) Pub. No.: US 2022/0415876 A1
(43) Pub. Date: Dec. 29, 2022

(54) CONTROLLED ELECTROSTATIC DISCHARGING TO AVOID LOADING ON INPUT/OUTPUT PINS

(71) Applicant: ADVANCED MICRO DEVICES, INC., SANTA CLARA, CA (US)

(72) Inventors: ROBERT S. RUTH, FORT COLLINS, CO (US); RAHUL AGARWAL, SANTA CLARA, CA (US); GLADNEY ASADA, SANTA CLARA, CA (US)

(21) Appl. No.: 17/360,832

(22) Filed: Jun. 28, 2021

(51) Int. Cl. H01L 27/02; H01L 23/488; H01L 23/00; H01L 23/50; H01L 23/528

(52) U.S. Cl. CPC H01L 27/0248; H01L 23/488; H01L 24/14; H01L 23/50; H01L 23/5286

(57) ABSTRACT

A chip for controlled electrostatic discharging to avoid loading on input/output pins, comprising: a die comprising: a first plurality of connector pins each conductively coupled to one or more signal paths, each of the first plurality of connector pins having a first height; and a second plurality of connector pins independent of any signal paths, each of the second plurality of connector pins having a second height greater than the first height.

### BACKGROUND

The packaging process of a chip exposes the chip to a risk of electrostatic discharge (ESD) when being bonded to a substrate. As the chip approaches the substrate for bonding and the distance between the chip and substrate decreases, there is a risk of static electricity flowing between the chip and the substrate, possibly damaging the internal components of the chip if the ESD flows through the I/O pins of the chip. Accordingly, chips typically include ESD protection in the signal pathways of the chip, such as diodes or other components. Such ESD protection provide for protection from ESD during packaging, but also increase the capacitance of the signal pathways, thereby degrading signal integrity, power, and performance.

### BRIEF DESCRIPTION OF THE DRAWINGS

FIG. 1A is a diagram of an example chip for controlled electrostatic discharging to avoid loading on input/output pins according to some embodiments.

FIG. 1B is a diagram of an example chip for controlled electrostatic discharging to avoid loading on input/output pins according to some embodiments.

FIG. 1C is a diagram of an example chip for controlled electrostatic discharging to avoid loading on input/output pins according to some embodiments.

FIG. 2A is a diagram of a portion of a packaging process for chip for controlled electrostatic discharging to avoid loading on input/output pins according to some embodiments.

FIG. 2B is a diagram of another portion of a packaging process for chip for controlled electrostatic discharging to avoid loading on input/output pins according to some embodiments.

FIG. 3A is a diagram of a portion of a packaging process for chip for controlled electrostatic discharging to avoid loading on input/output pins according to some embodiments.

FIG. 3B is a diagram of another portion of a packaging process for chip for controlled electrostatic discharging to avoid loading on input/output pins according to some embodiments.

FIG. 4 is a flowchart of an example method for controlled electrostatic discharging to avoid loading on input/output pins according to some embodiments.

FIG. 5 is a flowchart of another example method for controlled electrostatic discharging to avoid loading on input/output pins according to some embodiments.

### DETAILED DESCRIPTION

In some embodiments, a chip for controlled electrostatic discharging to avoid loading on input/output pins includes: a die including: a first plurality of connector pins each conductively coupled to one or more signal paths, each of the first plurality of connector pins having a first height; and a second plurality of connector pins independent of any signal paths, each of the second plurality of connector pins having a second height greater than the first height.

In some embodiments, each of the first plurality of connector pins has a first diameter and each of the second plurality of connector pins has a second diameter less than the first diameter er. In some embodiments, each of the first plurality of connector pins includes a respective first conductive pillar and a respective first solder bump and each of the second plurality of connector pins includes a respective second conductive pillar and a respective second solder bump. In some embodiments, a height of the respective first conductive pillar is substantially equal to a height of the respective second conductive pillar and a height of the respective first solder bump is less than a height of the respective second solder bump. In some embodiments, a height of the respective first conductive pillar is less than a height of the respective second conductive pillar. In some embodiments, one or more of the second plurality of connector pins are coupled to a power connection. In some embodiments, one or more of the second plurality of connector pins are coupled to a ground connection.

In some embodiments, an apparatus for controlled electrostatic discharging to avoid loading on input/output pins includes: a die including: a first plurality of connector pins each conductively coupled to one or more signal paths of the die, each of the first plurality of connector pins having a first height; a second plurality of connector pins independent of any signal paths of the die, each of the second plurality of connector pins having a second height greater than the first height; and a substrate coupled to the die via the first plurality of connector pins and the second plurality of connector pins.

In some embodiments, each of the first plurality of connector pins has a first diameter and each of the second plurality of connector pins has a second diameter less than the first diameter. In some embodiments, each of the first plurality of connector pins includes a respective first conductive pillar and a respective first solder bump and each of the second plurality of connector pins includes a respective second conductive pillar and a respective second solder bump. In some embodiments, a height of the respective first conductive pillar is substantially equal to a height of the respective second conductive pillar and a height of the respective first solder bump is less than a height of the respective second solder bump. In some embodiments, a height of the respective first conductive pillar is less than a height of the respective second conductive pillar. In some embodiments, one or more of the second plurality of connector pins are coupled to a power connection. In some embodiments, one or more of the second plurality of connector pins are coupled to a ground connection.

In some embodiments, a method for controlled electrostatic discharging to avoid loading on input/output pins includes: bonding, to a die, a first plurality of connector pins each conductively coupled to one or more signal paths, each of the first plurality of connector pins having a first height; and bonding, to the die, a second plurality of connector pins independent of any signal paths, each of the second plurality of connector pins having a second height greater than the first height.

In some embodiments, the method further includes coupling the die to a substrate via the first plurality of connector pins and the second plurality of connector pins. In some embodiments, the first plurality of connector pins include a plurality of first solder bumps applied to a plurality of first conductive pillars; and wherein the second plurality of connector pins include a plurality of second solder bumps applied to a plurality of first second conductive pillars. In some embodiments, the plurality of first conductive pillars and the plurality of second conductive pillars are of a same height; and the plurality of second solder bumps are of a greater height than the plurality of first solder bumps. In some embodiments, the plurality of second conductive pillars is of a greater height than the plurality of first conductive pillars. In some embodiments, the first plurality of connector pins each have a first diameter and the second plurality of connector pins each have a second diameter less than the first diameter.

During the packaging process, a chip is bonded with, coupled to, or applied to a substrate. As an example, an integrated circuit chip is packaged by being bonded to a printed circuit board (PCB) substrate. To bond the chip to a substrate, connector pins of the chip interface with holes, sockets, or other interfaces on the substrate. Such connector pins couple various pathways within the chip to the substrate. For example, input/output (I/O) pins (e.g., signal pins) couple signal pathways within the substrate to the chip, allowing for signals to be provided to or output from the chip. As another example, power pins allow for power to be provided to the chip via power pathways within the substrate. As a further example, ground pins provide ground connections for the chip via the substrate.

The packaging process exposes the chip to a risk of electrostatic discharge (ESD). As the chip approaches the substrate for bonding and the distance between the chip and substrate decreases, there is a risk of static electricity flowing between the chip and the substrate. The ESD has the possibility of damaging the internal components of the chip if the ESD flows through the I/O pins of the chip. Accordingly, chips typically include ESD protection in the signal pathways of the chip, such as diodes or other components. Such ESD protection provide for protection from ESD during packaging, but also increase the capacitance of the signal pathways, thereby degrading signal integrity, power, and performance.

During the packaging process, the chip approaches the substrate at a perpendicular angle relative to the substrate. As each connector pin is substantially equal in height and each connector pin maintains a substantially same distance from the substrate during approach, each connector pin is equally likely to receive an ESD from the substrate as each connector pin is equally likely to make contact with the substrate, or each connector pin will contact the substrate at the same time. Thus, there is no way to ensure that an ESD flows to a power or ground pin, where the risk of ESD damage is unlikely, as opposed to an I/O pin.

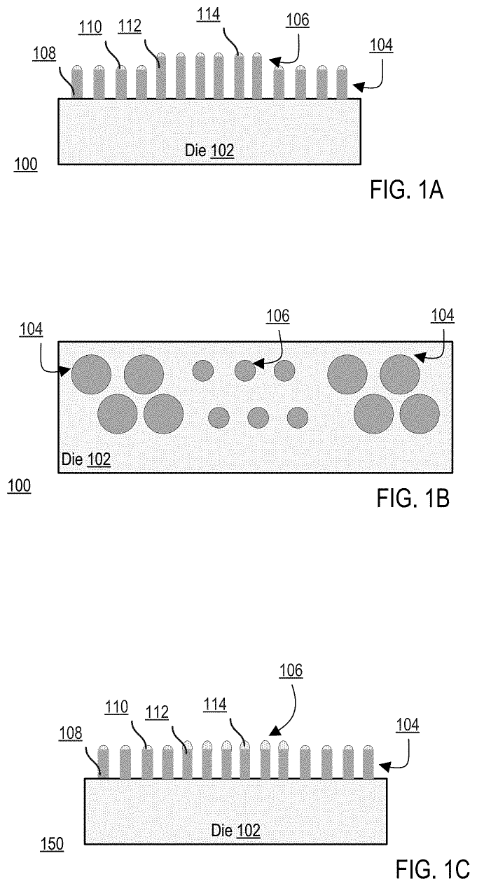

To address these concerns, FIG. 1A is a diagram of a non-limiting example chip 100. The example chip 100 of FIG. 1A is shown in a profile view. The example chip 100 can be implemented in a variety of computing devices, including mobile devices, personal computers, peripheral hardware components, gaming devices, set-top boxes, and the like. The chip 100 includes a die 102. The die 102 includes, for example, a silicon die 102a of an integrated circuit chip 100. The die 102 includes, for example various signal pathways, integrated circuits, and other function components as can be appreciated.

The chip 100 also includes a plurality connector pins 104. The connector pins 104 include, for example, I/O pins allowing the chip 100 to interface with one or more signal pathways of a substrate. Thus, when the chip 100 is packaged with a substrate, the connector pins 104 allow for signals travel between the chip 100 and the substrate. The chip 100 also includes a plurality of connector pins 106. The connector pins 106 include, for example, ground pins connecting the chip 100 to ground, power pins connecting the chip to a power source via a power pathway of a substrate, or combinations thereof.

In the example chip 100 of FIG. 1A, the connector pins 104 include conductive pillars 108 and solder bumps 110. Similarly, the connector pins 106 include conductive pillars 112 and solder bumps 114. The conductive pillars 108,112 are pins, rods, pillars, or other rigid or semi-rigid structures of conductive material such as copper. The solder bumps 110,114 are deposits of conductive alloys (e.g., tin-lead or tin-copper-lead) that are deposited onto their respective conductive pillars 108,112 in melted form. When cooled and solidified, the solder bumps 110,114 provide for a conductive bond between the respective conductive pillars 108,112 and the substrate. As an example, the solder bumps 110,114 are deposited onto their respective conductive pillars 108,112 prior to packaging the chip 100 to a substrate. After packaging, when the solder bumps 110,114 are cooled and solidified, the hardened solder bumps 110,114 provide for a structural and conductive connection between the chip 100 and the substrate.

In the example chip 100 of FIG. 1A, the conductive pillars 108 are shorter than the conductive pillars 112. That is, the conductive pillars 108 are of a height less than the conductive pillars 112. Accordingly, during packaging, the connector pins 106 maintain a closer distance to the substrate when compared to the connector pins 104. Thus, an ESD between the chip 100 and the substrate will flow through the connector pins 106, not the connector pins 104, as the connector pins 106 will contact the substrate before the connector pins 104. This prevents the signal pathways within the chip 100 from being damaged by ESD without the need for additional ESD protective components.

In some embodiments, the conductive pillars 108 are wider than the conductive pillars 112. That is, the conductive pillars 108 have a diameter greater than the diameter of the conductive pillars 112. In some embodiments, the diameter of a given conductive pillar 108,112 is proportional to the height of the given conductive pillar 108,112. For example, in some embodiments, the diameter of each conductive pillar 108,112 is proportional to their respective height such that a volume of each of the conductive pillars 108,112 is substantially the same. In some embodiments, the volume or height of the solder bumps 110,114 are each substantially the same.

One skilled in the art will appreciate that, in some embodiments, a substrate to which the chip 100 is packaged will require holes, sockets, or slots of varying diameters and depths in order to package the chip 100. For example, holes on the substrate for connector pins 106 will be narrower and deeper than the holes for the connector pins 104. One skilled in the art will appreciate that, in embodiments in which the connector pins 104,106 pass through the substrate to an opposing side, the depth of such holes will remain constant as they will traverse the entire substrate.

FIG. 1B shows an alternative view of the example chip 100 shown in FIG. 1A in an overhead view. In this overhead view, the solder bumps 110,114 are omitted for clarity and illustrative purposes to show the diameters of the conductive pillars 108,112. As seen in FIG. 1B, the connector pins 104 have a larger diameter than the connector pins 106. Thus, the critical dimension (CD) (e.g., the diameter) of the connector pins 104 and 106 are modulated in order to achieve the variance in height illustrated in FIG. 1A.

FIG. 1C is a diagram of another non-limiting example chip 150. The example chip 150 of FIG. 1C is similar to the example chip 100 of FIG. 1A in that the example chip 150 includes a die 102, and connector pins 104,106 each having respective conductive pillars 108,112 and solder bumps 110,114.

The example chip 150 of FIG. 1C differs from the example chip 100 of FIG. 1A in that the conductive pillars 108,112 of the connector pins 104,106 are coplanar (e.g., substantially coplanar). In other words, the conductive pillars 108,112 of the connector pins 104,106 are of substantially the same height. For example, in some embodiments, the conductive pillars 108,112 are inserted in or bonded to the die 102 and then planarized or leveled such that the resulting conductive pillars 108,112 are of substantially the same height. In some embodiments, the conductive pillars 108 are wider than the conductive pillars 112. That is, the conductive pillars 108 have a diameter greater than the diameter of the conductive pillars 112. In some embodiments, the diameter of a given conductive pillar 108,112 is proportional to the height of the given conductive pillar 108,112 prior to planarization.

The example chip 150 of FIG. 1C further differs from the example chip 100 of FIG. 1A in that the solder bumps 114 of the connector pins 106 have a height greater than the solder bumps 110 of the connector pins 104. Thus, the height of the connector pins 106 is greater than the height of the connector pins 104 by virtue of the height of the solder bumps 114 relative to the solder bumps 110. Accordingly, during packaging, the connector pins 106 maintain a closer distance to the substrate when compared to the connector pins 104 by virtue of the solder bumps 114 being closer to the substrate compared to the solder bumps 110. Thus, an ESD between the chip 100 and the substrate will flow through the connector pins 106, not the connector pins 104, as the connector pins 106 will contact the substrate before the connector pins 104. This prevents the signal pathways within the chip 100 from being damaged by ESD without the need for additional ESD protective components.

As ESD is preferentially discharged through the connector pins 106 rather than the connector pins 104, the connector pins 104 do not need ESD protective components such as diodes or other components. Thus, the signal pathways connected to the connector pins 104 do not suffer from any power, signal, or performance degradation caused by these ESD protective components.

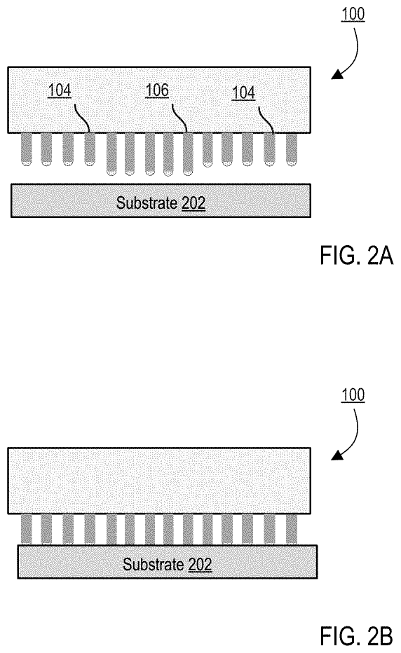

FIGS. 2A and 2B show an example packaging of a chip 100 to a substrate 202. The substrate 202 includes, for example, a PCB substrate 202. As is shown in FIG. 2A, the connector pins 106 are closer to the substrate 202 during packaging as the chip 100 approaches the substrate 202 by virtue of the greater height of the conductive pillars 112 compared to the conductive pillars 108. Accordingly, if an ESD occurs from the substrate 202 to the chip 100, the ESD will flow to the connector pins 106 instead of the connector pins 104 as the connector pins 106 will contact the substrate 202 before the connector pins 104. Thus, the connector pins 104 and their associated signal networks are protected from the ESD without the need for additional ESD protective components. The chip 100 is shown as bonded to the substrate 202 after packaging in FIG. 2B.

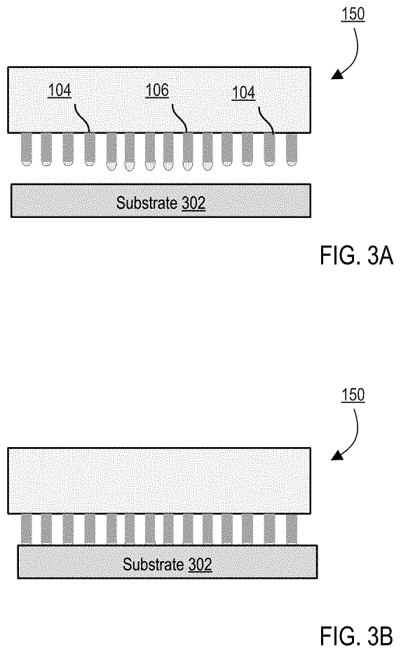

FIGS. 3A and 3B show an example packaging of a chip 150 to a substrate 302. The substrate 302 includes, for example, a PCB substrate 302. As is shown in FIG. 3A, the connector pins 106 are closer to the substrate 302 during packaging as the chip 150 approaches the substrate 302 by virtue of the greater height of the solder bumps 114 compared to the solder bumps 110. Accordingly, if an ESD occurs from the substrate 302 to the chip 150, the ESD will flow to the closer connector pins 106 instead of the connector pins 104 as the connector pins 106 will contact the substrate 302 before the connector pins 104. Thus, the connector pins 104 and their associated signal networks are protected from the ESD without the need for additional ESD protective components. The chip 150 is shown as bonded to the substrate 302 after packaging in FIG. 3B.

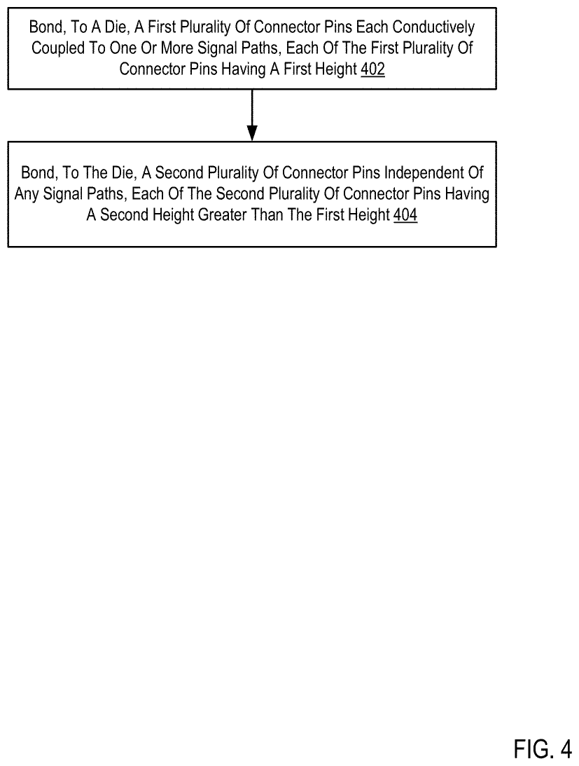

For further explanation, FIG. 4 sets forth a flow chart illustrating an example method for controlled electrostatic discharging to avoid loading on input/output pins that includes bonding 402, to a die 102 (e.g., of a chip 100 or a chip 150), a first plurality of connector pins 104 each conductively coupled to one or more signal paths, each of the plurality of connector pins 104 having a first height. In other words, the first plurality of connector pins 104 include, for example, I/O pins allowing a chip 100,150 to interface with one or more signal pathways of a substrate.

The method of FIG. 4 further includes bonding 404, to the die 102 (e.g., of the chip 100 or chip 150), a second plurality of connector pins 106 independent of any signal paths, each of the second plurality of connector pins 106 having a second height greater than the first height (e.g., of the first plurality of connector pins 104). The connector pins 106 include, for example, ground pins for ground connections, or power pins for connecting to a power source via a power pathway of a substrate, or combinations thereof. In other words, as the second plurality of connector pins 106 are not connected to a signal pathway of a chip 100,150, and are instead connected to power or ground, the second plurality of connector pins 106 are considered independent of the signal paths.

The first plurality of the connector pins 104 include conductive pillars 108 and solder bumps 110. Similarly, the second plurality of connector pins 106 include conductive pillars 112 and solder bumps 114. The conductive pillars 108,112 are pins, rods, pillars, or other rigid or semi-rigid structures of conductive material such as copper. The solder bumps 110,114 are deposits of conductive alloys (e.g., tin-lead or tin-copper-lead) that are deposited onto their respective conductive pillars 108,112 in melted form. When cooled and solidified, the solder bumps 110,114 provide for a conductive bond between the respective conductive pillars 108,112 and the substrate. As an example, the solder bumps 110,114 are deposited onto their respective conductive pillars 108,112 prior to packaging. After packaging, when the solder bumps 110,114 are cooled and solidified, the hardened solder bumps 110,114 provide for a structural and conductive connection with the substrate.

In some embodiments, each of the second plurality of connector pins 106 has a second height greater than the first height of the first plurality of connector pins because the conductive pillars 108 of the first plurality of connector pins 104 are shorter than the conductive pillars 112 of the second plurality of connector pins 106. In some embodiments, the conductive pillars 108 of the first plurality of connector pins 104 are wider than the conductive pillars 112 of the second plurality of connector pins 106. That is, the conductive pillars 108 of the first plurality of connector pins 104 have a diameter greater than the diameter of the conductive pillars 112 of the second plurality of connector pins 106. In some embodiments, the diameter of a given conductive pillar 108,112 is proportional to the height of the given conductive pillar 108,112. For example, in some embodiments, the diameter of each conductive pillar 108,112 is proportional to their respective height such that a volume of each of the conductive pillars 108,112 is substantially the same. In some embodiments, the volume or height of the solder bumps 110,114 are each substantially the same.

In some embodiments, each of the second plurality of connector pins 106 has a second height greater than the first height of the first plurality of connector pins because the solder bumps 110 of the first plurality of connector pins 104 are shorter than the solder bumps 114 of the second plurality of connector pins 106. In some embodiments, the conductive pillars 108,112 of both the first plurality of connector pins 104 and the second plurality of connector pins 106 are coplanar (e.g., substantially coplanar). In other words, the conductive pillars 108,112 of both the first plurality of connector pins 104 and the second plurality of connector pins 106 are of substantially the same height. The height differential between the first plurality of connector pins 104 and the second plurality of connector pins 106 is then achieved by a difference in height between their respective solder bumps 110,114.

For example, in some embodiments, the conductive pillars 108,112 of both the first plurality of connector pins 104 and the second plurality of connector pins 106 are inserted in or bonded to the die 102 and then planarized or leveled such that the resulting conductive pillars 108,112 of both the first plurality of connector pins 104 and the second plurality of connector pins 106 are of substantially the same height. In some embodiments, the conductive pillars 108 of the first plurality of connector pins 104 are wider than the conductive pillars 112 of the second plurality of connector pins 106. That is, the conductive pillars 108 of the first plurality of connector pins 106 have a diameter greater than the diameter of the conductive pillars 112 of the second plurality of connector pins 106. In some embodiments, the diameters of a given conductive pillar 108,112 is proportional to the height of the given conductive pillar 108,112 prior to planarization.

As the second plurality of connector pins 106 have a greater height than the first plurality of connector pins 104, the second plurality of connector pins 106 will be closer to a substrate during packaging, and will also contact the substrate first. Thus, ESD will be preferentially discharged through the second plurality of connector pins 106. As ESD is preferentially discharged through the second plurality of connector pins 106 rather than the first plurality of connector pins 104, the first plurality of connector pins 104 do not need ESD protective components such as diodes or other components. Thus, the signal pathways connected to the first plurality of connector pins 104 do not suffer from any power, signal, or performance degradation caused by these ESD protective components.

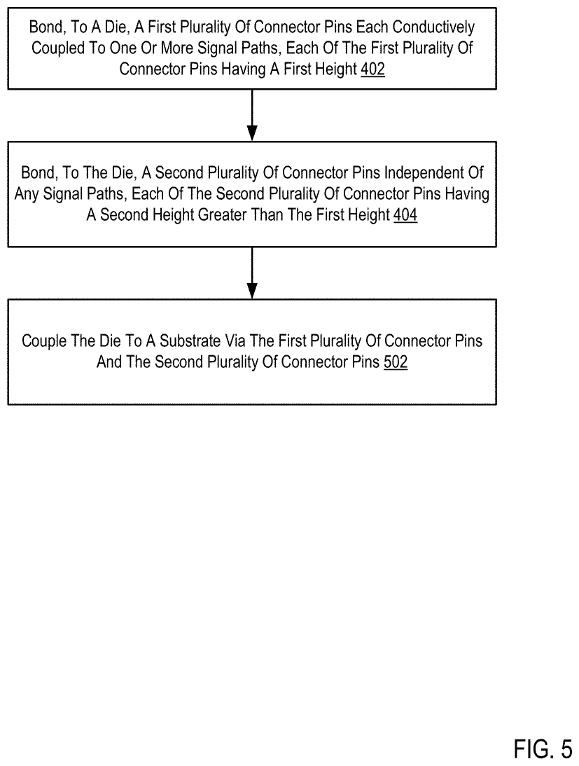

For further explanation, FIG. 5 sets forth a flow chart illustrating another example method for controlled electrostatic discharging to avoid loading on input/output pins according to embodiments of the present disclosure. The method of FIG. 5 is similar to FIG. 4 in that the method of FIG. 5 includes bonding 402, to a die 102, a first plurality of connector pins 104 each conductively coupled to one or more signal paths, each of the plurality of connector pins 104 having a first height; and bonding 404, to the die 102 (e.g., of the chip 100 or chip 150), a second plurality of connector pins 106 independent of any signal paths, each of the second plurality of connector pins 106 having a second height greater than the first height.

The method of FIG. 5 differs from FIG. 4 in that the method of FIG. 5 also includes coupling 502 the die 102 to a substrate 202,302 via the first plurality of connector pins 104 and the second plurality of connector pins 106. The die 102 is coupled 502 to the substrate 202, 302 during a packaging process. Coupling 502 the die 102 to a substrate 202,302 includes interfacing with the substrate 202,302 via the first plurality of connector pins 104 and the second plurality of connector pins 106. For example, the first plurality of connector pins 104 and the second plurality of connector pins 106 interface with holes, slots, sockets, and the like of the substrate 202,302. Such interfacing couples the first plurality of connector pins 104 to the signal pathways of the substrate 202,302, and couples the second plurality of connector pins 106 to ground or power connections of the substrate 202,302. During coupling, if an ESD occurs, the ESD will flow through the second plurality of connector pins 106 by virtue of their closer distance and earlier contact to the substrate 202,302 relative to the first plurality of connector pins 104.

In view of the explanations set forth above, readers will recognize that the benefits of controlled electrostatic discharging to avoid loading on input/output pins include:
Improved performance of a computing system by preferentially discharging ESD through ground or power pins as opposed to I/O pins of a chip.
Improved performance of a computing system by [EXAMPLE] protecting I/O pins from ESD without the need for additional ESD protective components such as diodes, thereby improving the overall signal strength, power, and integrity of the signal pathways of the chip.

It will be understood from the foregoing description that modifications and changes can be made in various embodiments of the present disclosure. The descriptions in this specification are for purposes of illustration only and are not to be construed in a limiting sense. The scope of the present disclosure is limited only by the language of the following claims.

What is claimed is:

1. A chip for controlled electrostatic discharging to avoid loading on input/output pins, comprising:
a die comprising:
a first plurality of connector pins each conductively coupled to one or more signal paths, each of the first plurality of connector pins having a first height; and
a second plurality of connector pins independent of any signal paths, each of the second plurality of connector pins having a second height greater than the first height.

2. The chip of claim 1, wherein each of the first plurality of connector pins has a first diameter and each of the second plurality of connector pins has a second diameter less than the first diameter.

3. The chip of claim 1, wherein each of the first plurality of connector pins comprises a respective first conductive pillar and a respective first solder bump and wherein each of the second plurality of connector pins comprises a respective second conductive pillar and a respective second solder bump.

4. The chip of claim 3, wherein a height of the respective first conductive pillar is substantially equal to a height of the respective second conductive pillar and a height of the respective first solder bump is less than a height of the respective second solder bump.

5. The chip of claim 3, wherein a height of the respective first conductive pillar is less than a height of the respective second conductive pillar.

6. The chip of claim 1, wherein one or more of the second plurality of connector pins are coupled to a power connection.

7. The chip of claim 1, wherein one or more of the second plurality of connector pins are coupled to a ground connection.

8. An apparatus for controlled electrostatic discharging to avoid loading on input/output pins, comprising:
a die comprising:
a first plurality of connector pins each conductively coupled to one or more signal paths of the die, each of the first plurality of connector pins having a first height;
a second plurality of connector pins independent of any signal paths of the die, each of the second plurality of connector pins having a second height greater than the first height; and
a substrate coupled to the die via the first plurality of connector pins and the second plurality of connector pins.

9. The apparatus of claim 8, wherein each of the first plurality of connector pins has a first diameter and each of the second plurality of connector pins has a second diameter less than the first diameter.

10. The apparatus of claim 8, wherein each of the first plurality of connector pins comprises a respective first conductive pillar and a respective first solder bump and wherein each of the second plurality of connector pins comprises a respective second conductive pillar and a respective second solder bump.

11. The apparatus of claim 10, wherein a height of the respective first conductive pillar is substantially equal to a height of the respective second conductive pillar and a height of the respective first solder bump is less than a height of the respective second solder bump.

12. The apparatus of claim 10, wherein a height of the respective first conductive pillar is less than a height of the respective second conductive pillar.

13. The apparatus of claim 8, wherein one or more of the second plurality of connector pins are coupled to a power connection.

14. The apparatus of claim 8, wherein one or more of the second plurality of connector pins are coupled to a ground connection.

15. A method for controlled electrostatic discharging to avoid loading on input/output pins, comprising:
bonding, to a die, a first plurality of connector pins each conductively coupled to one or more signal paths, each of the first plurality of connector pins having a first height; and
bonding, to the die, a second plurality of connector pins independent of any signal paths, each of the second plurality of connector pins having a second height greater than the first height.

16. The method of claim 15, further comprising coupling the die to a substrate via the first plurality of connector pins and the second plurality of connector pins.

17. The method of claim 15:
wherein the first plurality of connector pins comprise a plurality of first solder bumps applied to a plurality of first conductive pillars; and
wherein the second plurality of connector pins comprise a plurality of second solder bumps applied to a plurality of first second conductive pillars.

18. The method of claim 17:
wherein the plurality of first conductive pillars and the plurality of second conductive pillars are of a same height; and
wherein the plurality of second solder bumps is of a greater height than the plurality of first solder bumps.

19. The method of claim 17, wherein the plurality of second conductive pillars is of a greater height than the plurality of first conductive pillars.

20. The method of claim 17, wherein each of the first plurality of connector pins has a first diameter and each of the second plurality of connector pins has a second diameter less than the first diameter.
